(19) United States
(12) Patent Application Publication
(10) Pub. No.: US 2003/0218236 A1
(43) Pub. Date: Nov. 27, 2003

(54) Chip carrier tape

(76) Inventors: Lance Cole Wright, Van Alstyne, TX (US); Albert Dulay Escusa, Garland, TX (US)

Correspondence Address: TEXAS INSTRUMENTS INCORPORATED, P O BOX 655474, M/S 3999, DALLAS, TX, 75265

(21) Appl. No.: 10/155,684

(22) Filed: May 24, 2002

(51) Int. Cl. H01L 21/44; H01L 23/495

(52) U.S. Cl. 257/668; 438/123; 257/670; 257/677; 257/666

(57) ABSTRACT

A chip carrier tape, which includes a tape member and a plurality of pockets, is provided. The plurality of pockets are formed in and along the tape member. Each of the pockets includes a first portion and a second portion. The first portion has a shape and size adapted to fit a first chip size therein. The second portion has a shape and size adapted to fit a second chip size therein. The first chip size differs from the second chip size. The first portion has a first pocket volume that is not part of the second portion, and the second portion has a second pocket volume that is not part of the first portion. There may be a second and different plurality of pockets formed in and along the tape member as well. Also a method of selling integrated circuit chips is provided.

### TECHNICAL FIELD

The present invention generally relates to tape and reel carriers used for shipping chips. In one aspect, it relates to a chip carrier tape adapted to carry multiple chip sizes.

### BACKGROUND

Some manufacturers produce semiconductor chips at one geographical location and have the chips packaged at another geographical location. Also, some manufacturers ship large quantities of packaged chips to other geographical locations. In such cases, the chips (packaged or unpackaged) are often delivered in a tape and reel package. A conventional tape and reel shipping package 40 is shown in FIG. 1. FIG. 2 shows an enlarged top view of a portion of a tape member 44 from FIG. 1. As shown in FIG. 2, the tape member 44 has a series of pockets 48 formed therein. Each pocket 48 has a shape and size designed to contain a certain size chip. In FIG. 2, one of the pockets 48 is shown with a chip 52 therein. After the chips 52 are placed in the pockets 48 of a tape member 44, a film cover is often temporarily bonded to the tape member 44 to contain the chips 52 within the pockets 48. Then with the chips 52 enclosed within the pockets 48, the loaded tape member 44 is wound onto a reel 56, as shown in FIG. 1, much like a film strip for a film projector is stored on a reel. The loaded reel 56 may then be boxed and/or stacked with other loaded reels to create a shipping package ready for delivery to another location.

FIG. 3 shows a cross-section view of one of the pockets 48 shown in FIG. 2 taken along line 3-3. FIG. 4 shows a cross-section view of the pocket 48 shown in FIGS. 2 and 3 taken along line 4-4. FIG. 5 shows a cross-section view of the pocket 48 (shown in FIG. 2) with the chip 52 therein, as taken along line 5-5. The tape member 44 has a row of holes 60 running along each side of the tape member 44 (see FIG. 2). These holes 60 may be used when feeding the tape member 44 through a machine (not shown) while loading/unloading chips to/from the tape member 44, for example. These holes 60 may be useful for indexing the position of the pockets 48 and for engaging the tape member 44 with corresponding drive gears.

In conventional tape members, the pockets are designed for a carrying a single chip in each pocket. Industry standards require that a pocket limits the movement of the chip within the pocket so that the chip will not be damaged during shipping. Even though a smaller chip may be placed in a pocket designed for a larger chip, the smaller chip may not be sufficiently constrained within the pocket to meet industry standards for constraining the chip during shipping to prevent damage to the chip. Thus, each chip design of a given size and shape usually requires its own set of tape and reel packages having pockets specifically shaped and sized for that chip design.

### BRIEF SUMMARY OF THE INVENTION

It would be more desirable and more economical to have a tape and reel package that can accommodate two or more different chip sizes and/or shapes. The problems and needs outlined above are addressed by certain aspects of the present invention. In accordance with one aspect of the present invention, a chip carrier tape is provided. The chip carrier tape includes a tape member and a plurality of pockets. The plurality of pockets are formed in and along the tape member. Each of the pockets includes a first portion and a second portion. The first portion has a shape and size adapted to fit a first chip size therein. The second portion has a shape and size adapted to fit a second chip size therein. The first chip size differs from the second chip size. The first portion has a first pocket volume that is not part of the second portion, and the second portion has a second pocket volume that is not part of the first portion. There may be a second and different plurality of pockets formed in and along the tape member as well.

In accordance with another aspect of the present invention, a chip carrier tape is provided. This chip carrier tape includes a tape member and a plurality of pockets. The plurality of pockets are formed in and along the tape member. Each of the pockets has a cross shape formed from a first portion intersecting a second portion. The first portion has a shape and size adapted to fit a first chip size therein. The second portion has a shape and size adapted to fit a second chip size therein. The first chip size differs from the second chip size.

In accordance with still another aspect of the present invention, a chip carrier tape is provided. This chip carrier tape includes a tape member and a plurality of pockets. The plurality of pockets are formed in and along the tape member. Each of the pockets has a first portion and a second portion. The first portion has a shape and size adapted to fit a first chip size therein, and the first portion is located at a first pocket depth. The second portion has a shape and size adapted to fit a second chip size therein, and the second portion is located at-a second pocket depth. The first chip size differs from the second chip size, and the first pocket depth differs from the second pocket depth.

In accordance with yet another aspect of the present invention, a chip carrier tape is provided. This chip tape carrier includes a tape member and a plurality of pockets. The plurality of pockets are formed in and along the tape member. Each of the pockets includes a main portion and a first slotted portion. The first slotted portion intersects the main portion, and the first slotted portion is adapted to receive a tab insert therein. A first chip portion of the pocket is defined within the main portion when the tab insert is located within the first slotted portion. The first chip portion has a shape and size adapted to fit a first chip size therein. A second chip portion of the pocket is defined within the main portion and across the first slotted portion when the tab insert is absent from the first slotted portion. The second chip portion has a shape and size adapted to fit a second chip size therein. The first chip size differs from the second chip size.

In accordance with another aspect of the present invention, a method of selling integrated circuit chips after the chips are fabricated is provided. The method includes the following step, the order of which may vary. First, a chip carrier tape is provided. The chip carrier tape includes a tape member and a plurality of pockets. The plurality of pockets are formed in and along the tape member. Each of the pockets includes a first portion and a second portion. The first portion has a shape and size adapted to fit a first chip size therein. The second portion has a shape and size adapted to fit a second chip size therein. The first chip size differs from the second chip size. The first portion has a first pocket volume that is not part of the second portion, and the second portion has a second pocket volume that is not part of the first portion. Second, at least one integrated circuit chip is loaded into at least one of the pockets. Third, the chip carrier tape, which is at least partially loaded, is delivered to a chip buyer.

### BRIEF DESCRIPTION OF THE DRAWINGS

The above features of the present invention will be more clearly understood from consideration of the following descriptions in connection with accompanying drawings in which:

FIG. 1 shows perspective view of a conventional tape and reel package;

FIG. 2 shows an enlarged top view for a portion of a tape member of FIG. 1;

FIG. 3 shows a cross-section view of a pocket from FIG. 2 taken along line 3-3;

FIG. 4 shows a cross-section view of a pocket from FIG. 2 taken along line 4-4;

FIG. 5 shows a cross-section view of a pocket from FIG. 2 taken along line 5-5;

FIG. 6 shows a top view for a portion of a chip carrier tape in accordance with a first embodiment of the present invention;

FIG. 7 shows a cross-section view of a pocket from FIG. 6 taken along line 7-7;

FIG. 8 shows a cross-section view of the pocket from FIG. 6 taken along line 8-8;

FIG. 9 shows a cross-section view of another pocket from FIG. 6 taken along line 9-9;

FIGS. 10-12 show variations on FIG. 9;

FIG. 13 shows a top view for a portion of a chip carrier tape in accordance with a second embodiment of the present invention;

FIGS. 14-17 show cross-section views of a pocket from FIG. 13 taken along line 14-14, 15-15, 16-16, and 17-17, respectively;

FIG. 18 shows a top view of a pocket for a chip carrier tape in accordance with a third embodiment of the present invention;

FIGS. 19 and 20 show cross-section views for the pocket of FIG. 18 taken along lines 19-19 and 20-20, respectively;

FIG. 21 shows a top view for a portion of a chip carrier tape in accordance with a fourth embodiment of the present invention;

FIGS. 22-27 show cross-section views of a pocket from FIG. 21 taken along line 22-22, 23-23, 24-24, 25-25, 26-26, and 27-27, respectively;

FIG. 28 shows a pocket from FIG. 21 with two chips loaded therein;

FIG. 29 shows a top view for a portion of a chip carrier tape in accordance with a fifth embodiment of the present invention;

FIG. 30 shows a cross-section view of a pocket from FIG. 29 taken along line 30-30;

FIG. 31 shows a top view for a pocket of a chip carrier tape in accordance with a sixth embodiment of the present invention;

FIG. 32 shows a top view for a pocket of a chip carrier tape in accordance with a seventh embodiment of the present invention;

FIG. 33 shows a top view for a pocket of a chip carrier tape in accordance with an eighth embodiment of the present invention; and

FIG. 34 shows a cross-section view of a pocket from FIG. 33 taken along line 34-34.

### DETAILED DESCRIPTION OF PREFERRED EMBODIMENTS

Referring now to the drawings, wherein like reference numbers are used herein to designate like elements throughout the various views, preferred embodiments of the present invention are illustrated and described. As will be understood by one of ordinary skill in the art, the figures are not necessarily drawn to scale, and in some instances the drawings have been exaggerated and/or simplified in places for illustrative purposes only. One of ordinary skill in the art will appreciate the many applications and variations of the present invention in light of the following description of the preferred embodiments of the present invention. The preferred embodiments discussed herein are illustrative examples of the present invention and do not limit the scope of the invention to the preferred embodiments described.

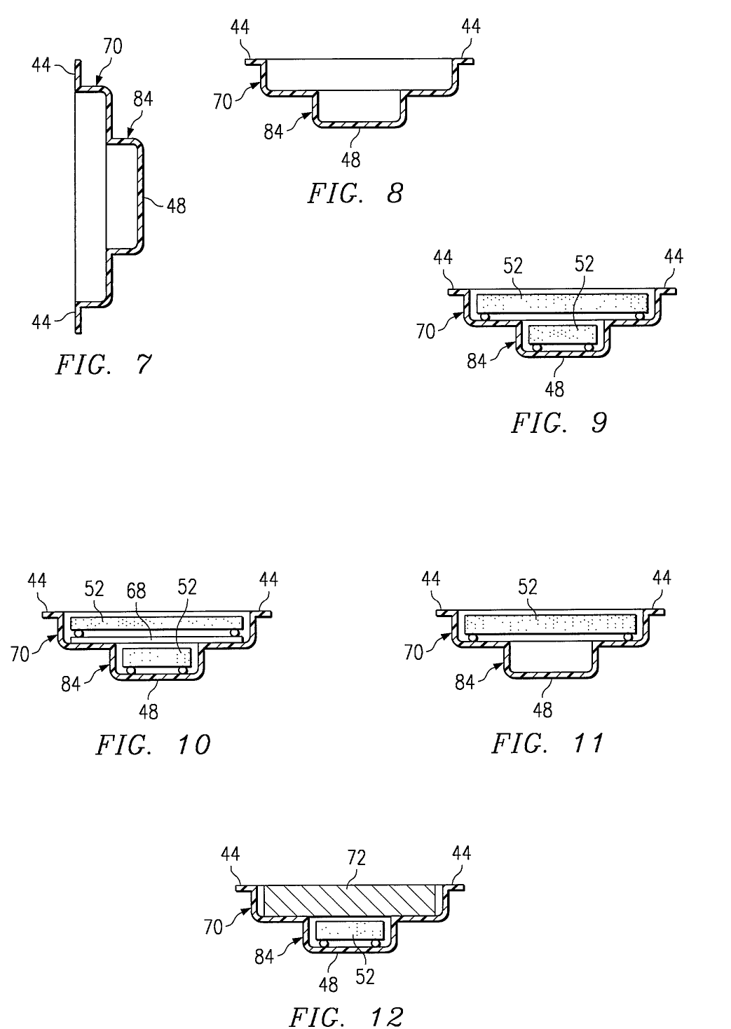

The term “chip” is used herein to generically refer to packaged chips (e.g., assembled with lead frame pins or board pins) and/or chips not yet packaged. Generally, an embodiment of the present invention provides a chip carrier tape having pockets adapted to carry multiple chip sizes and/or shapes within each pocket. A first embodiment of the present invention is shown in FIGS. 6-12. FIG. 6 shows a top view of a portion of a chip carrier tape 62 in accordance with the first embodiment. Each of the pockets 48 shown in FIG. 6 is formed in the tape member 44 and is adapted to retain up to two chips 52 (each of a different size) therein. FIG. 7 shows a cross-section view for one of the pockets 48 shown in FIG. 6 taken along line 7-7. FIG. 8 shows a cross-section view for the pocket 48 shown in FIG. 6 taken along line 8-8. As shown in FIGS. 7 and 8, the pockets 48 of the first embodiment have a depth that allows for two chips 52 to be retained within a pocket 48. Referring to FIG. 6 again, another pocket 48 is shown with two chips 52 therein. FIG. 9 shows a cross-section view for the pocket 48 with chips 52 therein of FIG. 6 as taken along line 9-9. Although not shown in FIGS. 6 and 9, FIG. 10 shows how a separator 68 may be included within the pocket 48 between the chips 52 to better retain the lower chip 52. However, in some cases, such a separator 68 may not be needed. In another embodiment (not shown), the pocket 48 may be adapted to retain one chip size in two different orientations.

FIGS. 11 and 12 show cross-section views of a pocket 48 in accordance with the first embodiment, each with only one chip 52 therein. In FIG. 11, due to the configuration of the upper portion 70, the upper chip 52 is sufficiently retained whether the lower chip 52 is present or not. However in FIG. 12, when the lower chip 52 is alone within the pocket 48, the pocket 48 will not sufficiently retain the lower chip 52 because it will be free to move into and about the upper portion 70 of the pocket 48. Thus, as shown in FIG. 12, a spacer block 72 may be needed to better retain the lower chip 52 when the upper chip 52 is not present. The spacer block 72 may be a piece of plastic, for example, having dimensions similar to that of the upper portion 70 of the pocket 48 (i.e., similar to that of an upper chip size that the upper pocket portion 70 is designed to retain). Preferably, the spacer block 72 may have adhesive on its top side 74 so that it sticks to the film cover that goes over the top of the tape member 44 during shipping. Thus when the spacer block 72 is adhered to the film cover, it will be removed from the pocket 48 when the film cover is peeled away. In such case where the spacer block 72 is adapted to be adhered to the film cover, it may be feasible to have a smaller spacer block (not shown) (i.e., not of similar size to the upper pocket portion 70) as the adhesive will maintain the position of the spacer block above the lower chip. A loaded chip carrier tape 62 in accordance with the first embodiment may be wound onto a reel 56 just as with a conventional chip carrier tape 62 (see e.g., FIG. 1). Thus, the first embodiment may be implemented with existing reels.

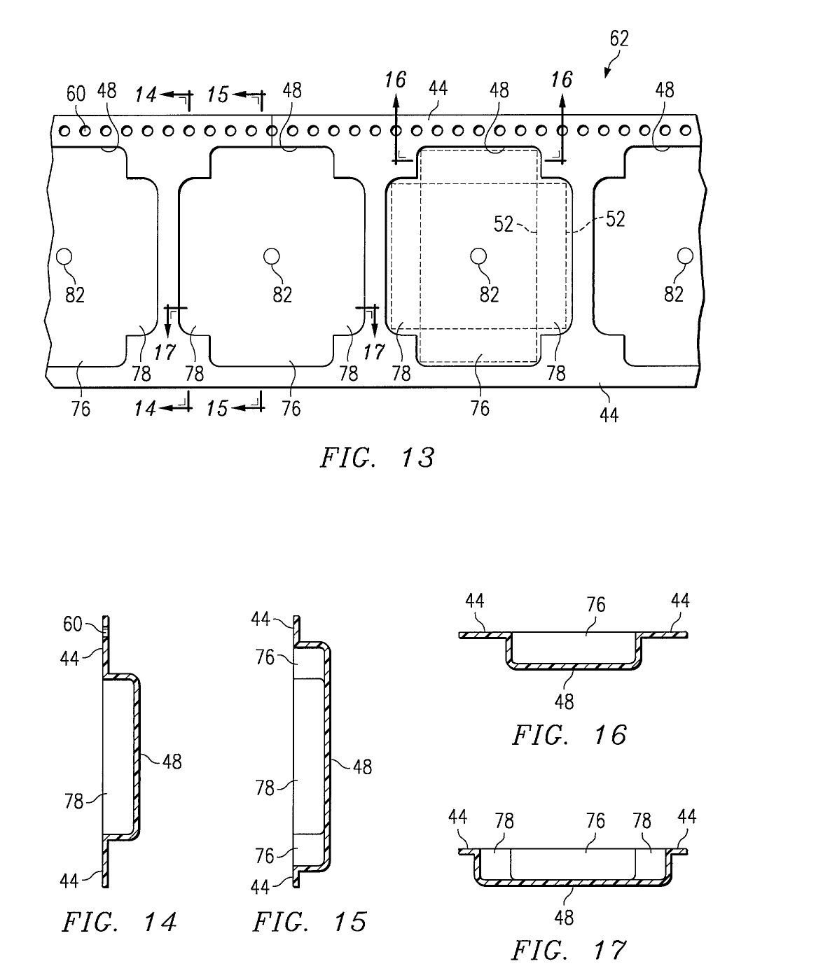

FIGS. 13-17 show a second embodiment of the present invention. FIG. 13 shows a top view of a portion of a chip carrier tape 62 in accordance with the second embodiment. Each of the pockets 48 shown in FIG. 13 has a cross shape formed from a first portion 76 intersecting a second portion 78. The first portion 76 has a shape and size adapted to fit a first chip size therein. The second portion 78 has a shape and size adapted to fit a second chip size therein. The first chip size differs from the second chip size. One of the pockets 48 in FIG. 13 shows the placement of chips 52 in the pocket 48 in phantom lines. Each of the pockets 48 shown in FIG. 13 is formed in the tape member 44 and is adapted to retain one chip 52 at a time. Hence, a chip 52 retained in one of the pockets 48 shown in FIG. 13 at a given time may be of the first chip size or the second chip size. FIG. 14 shows a cross-section view for one of the pockets 48 shown in FIG. 13 taken along line 14-14. FIG. 15 shows a cross-section view for the pocket 48 shown in FIGS. 13 and 14 taken along line 15-15. FIGS. 16 and 17 show cross-section views for the pocket 48 shown in FIGS. 13-15 taken along lines 16-16 and 17-17, respectively. If the depth of the pocket 48 were increased, the second embodiment could be modified to retain two or more chips in a stacked configuration.

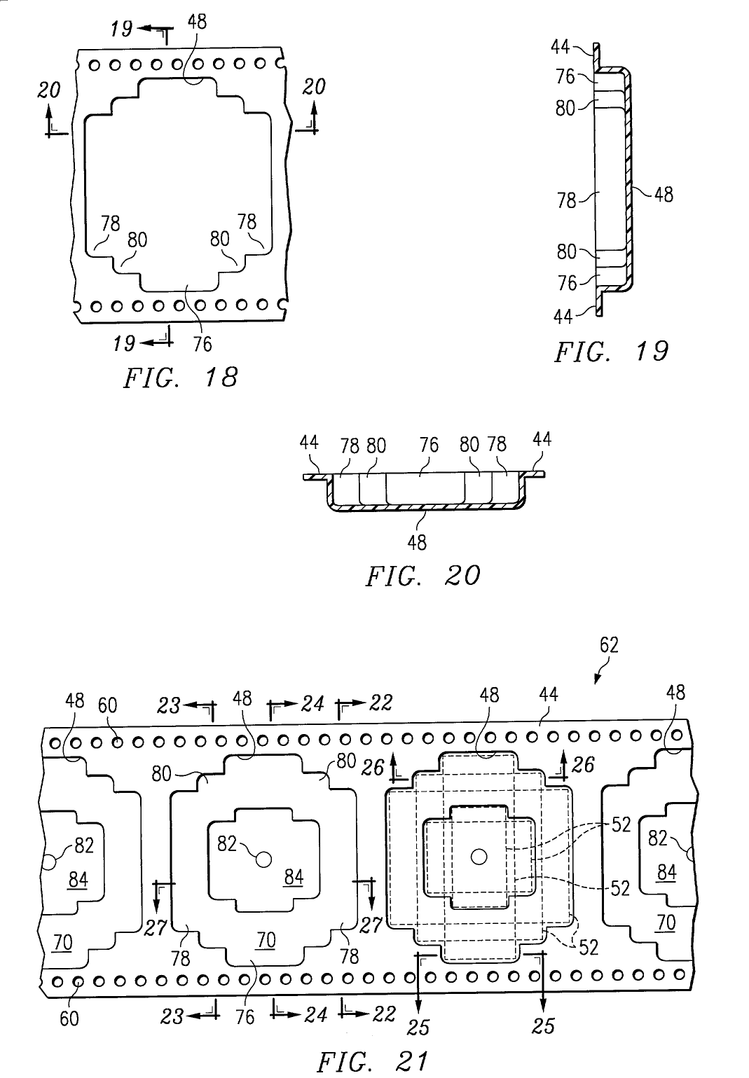

FIGS. 18-20 show a pocket 48 of a third embodiment of the present invention. FIG. 18 shows a top view of the pocket 48, which is part of a chip carrier tape with multiple pockets (remainder not shown). FIGS. 19 and 20 show cross-section views for the pocket 48 shown in FIG. 18 taken along lines 19-19 and 20-20, respectively. The pocket 48 in FIG. 18 has a cross shape formed from a first portion 76 intersecting a second portion 78 as in the second embodiment. But in addition, the third embodiment has a third portion 80 that intersects or overlaps with the first and second portions 76 and 78. The first portion 76 has a shape and size adapted to fit a first chip size therein. The second portion 78 has a shape and size adapted to fit a second chip size therein. And, the third portion 80 has a shape and size adapted to fit a third chip size. The first, second, and third chip sizes differ from each other. Hence, the third embodiment can retain three different chip sizes with a single pocket design. The pocket 48 of the third embodiment is adapted to retain one chip at a time. However, if the depth of the pocket 48 were increased, the third embodiment could be modified to retain two or more chips in a stacked configuration.

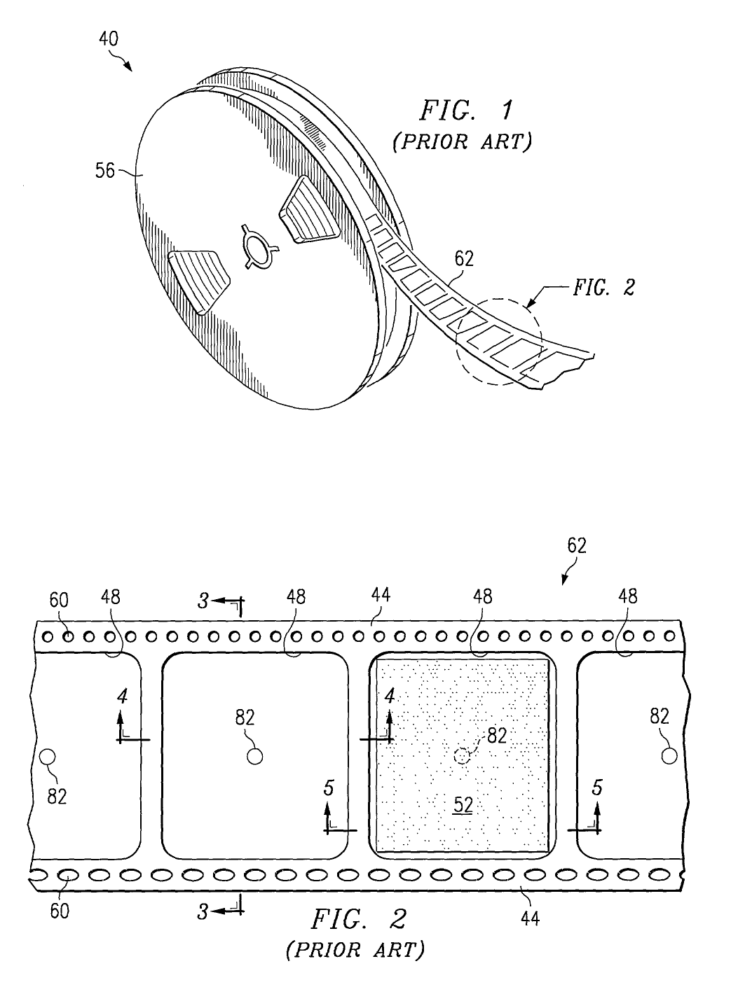

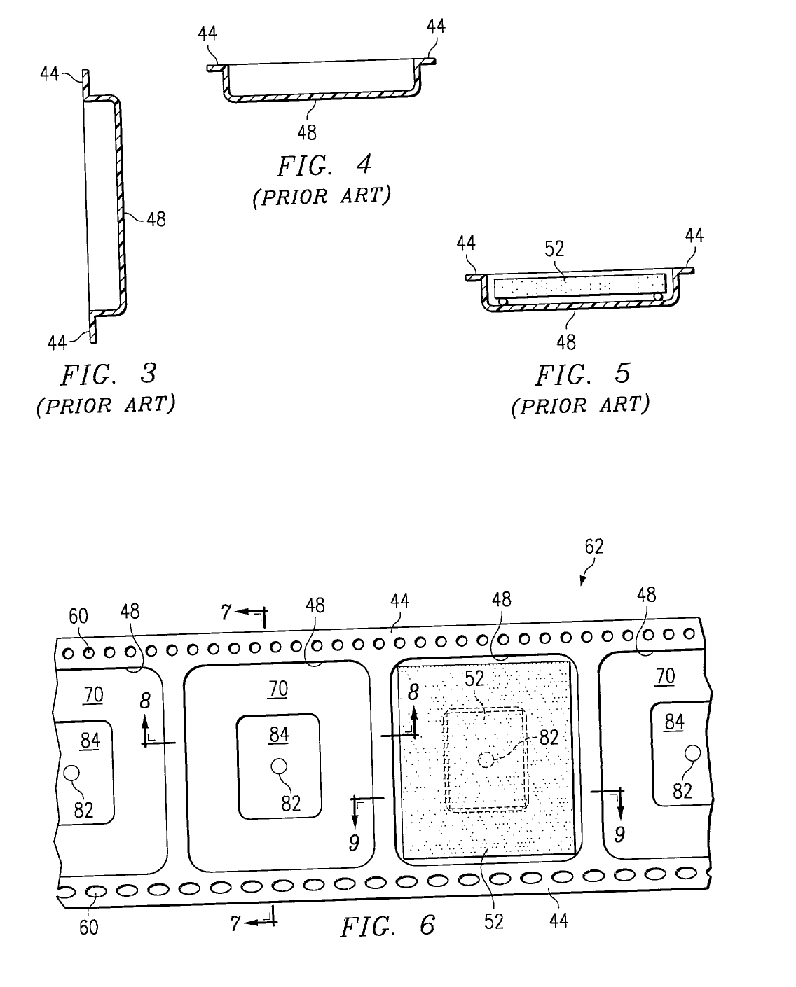

Referring again to FIGS. 2, 6, and 13, note that these pockets 48 have a hole 82 formed therethrough. The hole 82 is an industry standard used by some equipment as an inspection hole to determine whether a chip 52 is present in the pocket 48. In contrast, the pocket 48 of the third embodiment lacks such a hole 82. Thus, an embodiment of the present invention may or may not have such a hole 82 formed in the bottom of the pocket 48.

Referring yet again to FIGS. 2 and 6, note that the tape members 44 shown in these figures have two rows of holes 60 for engagement with a drive sprocket (not shown), for example. But in contrast, the second embodiment shown in FIG. 13 has only one row of holes 60. In another embodiment (not shown), the tape member 44 may have no row of holes. Industry standard EIA-481 (revision B) provides that on chip carrier tape having a width of 32 mm or larger, there should be two rows of sprocket holes 60. For such cases, the industry standard states that a first row of sprocket holes 60 has round holes, and the second row of sprocket holes 60 has elongated holes. And for chip carrier tape 62 having a width less than 32 mm, there should be only one row of round holes 60. Thus, an embodiment of the present invention may or may not have one or more rows of holes 60 extending along the tape member 44, the number of rows (if used) may vary, and the shape of the holes may vary.

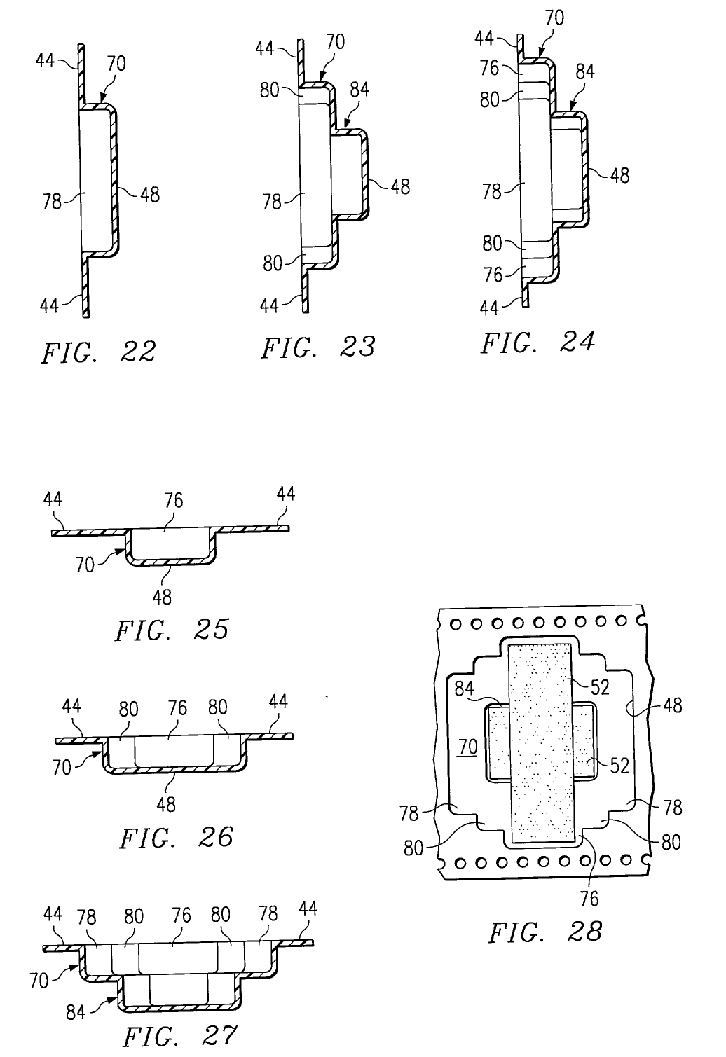

FIGS. 21-28 show a fourth embodiment of the present invention. FIG. 21 shows a top view of a portion of a chip carrier tape 62 in accordance with the fourth embodiment. FIGS. 22-27 show cross-section views for one of the pockets 48 shown in FIG. 21 taken along lines 22-22, 23-23, 24-24, 25-25, 26-26, and 27-27, respectively. In the fourth embodiment, each of the pockets 48 shown in FIG. 21 has two levels of depth 70 and 84, as best shown in FIGS. 23, 24, and 27. The upper level 70 of the pocket 48 has a cross shape formed by three intersecting and overlapping portions, where each portion is adapted to retain a different chip size (as in the third embodiment of FIGS. 18-20). The lower level 84 of the pocket 48 has a cross shape formed by two intersecting portions, where each of these portions is adapted to retain a different chip size (as in the second embodiment of FIGS. 13-17). Hence, each pocket 48 of the fourth embodiment is adapted to retain five different chip sizes and is adapted to retain up to a total of two chips 52 at a time. FIG. 28 shows a top view of a pocket 48 in accordance with the fourth embodiment (remainder of tape member 44 not shown) having two chips 52, each of a different size) loaded into the pocket 48. The fourth embodiment therefore illustrates that the described embodiments may be mixed and/or combined to form other embodiments of the present invention.

Although the orientation of intersecting portions in the pockets 48 described herein are parallel or orthogonal with respect to each other (see e.g., FIGS. 13, 18, and 21), this need not be the case. Such portions may intersect at any angle. With the benefit of this disclosure, one of ordinary skill in the art will realize many other possible embodiments of the present invention.

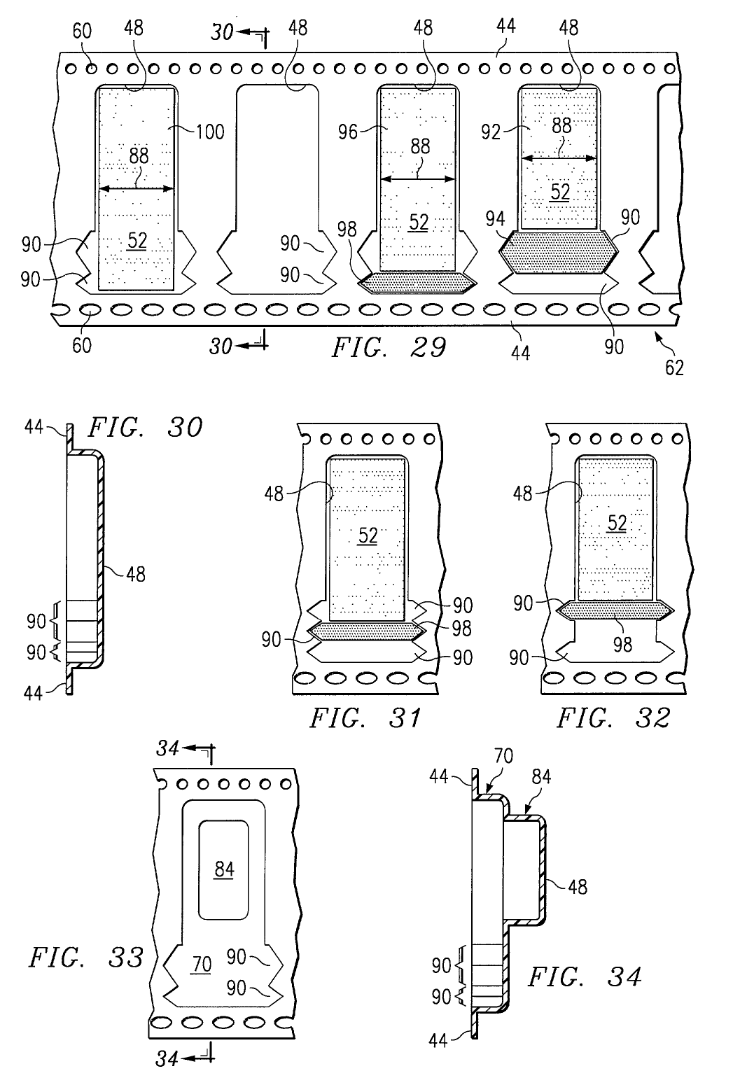

FIGS. 29-30 show a fifth embodiment of the present invention. FIG. 29 shows a top view of a portion of a chip carrier tape 62 in accordance with the fifth embodiment. FIG. 30 shows a cross-section view for one of the pockets 48 shown in FIG. 29 taken along lines 30-30. Each pocket 48 of the fifth embodiment is adapted to retain three different chip sizes having a common width dimension 88, and is adapted to retain one chip 52 at a time. Each pocket 48 has two slot sections 90 that may be used to “adjust” the length of the pocket 48 (i.e., make it shorter or longer). In other alternative embodiments (not shown), there may be only one slot section 90 or there may be more than two slot section 90 per pocket 48. Three of the pockets 48 shown in FIG. 29 have chips 52 therein (one chip 52 in each of the three pockets 48), and the chips 52 are different sizes. When the shortest chip 92 is loaded in a pocket 48, a first insert tab 94 may be used to adjust the length of the pocket 48. Similarly, when the mid-length chip 96 is loaded in a pocket 48, a second insert tab 98 may be used to adjust the length of the pocket 48. When the longest chip 100 is loaded in a pocket 48, no insert tab is needed. If desired, an insert tab (94, 98) may have adhesive applied to its top side so that it adheres to the film cover, and/or adhesive applied to its bottom side so that it adheres to the bottom of the pocket 48.

As illustrated in FIG. 31, the sizes of the slot sections 90 are preferably the same to allow a single insert tab size to be used for any of the slot sections 90. FIG. 31 shows a pocket 48 with a chip 52 therein and an insert tab 98 inserted into one of the slot sections 90 to retain the position of the chip 52 in accordance with a sixth embodiment of the present invention (remainder of the chip carrier tape 62 and other pockets 48 not shown). Hence, the pocket 48 of the sixth embodiment is adapted to retain four different chip sizes and is adapted to hold one chip 52 at a time.

As illustrated in FIG. 32, the slot sections 90 do not necessarily have to be together (abutting each other). However, the slot sections 90 could also overlap each other. FIG. 32 shows a pocket 48 with a chip 52 therein and an insert tab 98 inserted into one of the slot sections 90 to retain the position of the chip 52 in accordance with a seventh embodiment of the present invention (remainder of the chip carrier tape 62 and other pockets 48 not shown). Hence, the pocket of the seventh embodiment is adapted to retain three different chip sizes and is adapted to hold one chip 52 at a time.

FIGS. 33 and 34 shows a pocket 48 in accordance with an eighth embodiment of the present invention (remainder of the chip carrier tape 62 and other pockets 48 not shown). FIG. 33 shows a top view of the pocket 48. FIG. 34 shows a cross-section view for the pocket 48 shown in FIG. 33 taken along line 34-34. The pockets 48 of the eighth embodiment are similar to those of the fifth embodiment (see FIG. 29), but with an added portion at a second level 84 of pocket depth. Hence, the pocket 48 shown in FIGS. 33 and 34 is adapted to hold three different chip sizes (one chip 52 at a time) in the upper portion 70 of the pocket 48, and is adapted to hold one chip size in the lower portion 84 of the pocket 48. And thus, the pocket 48 shown in FIGS. 33 and 34 may retain up to two chips 52 at a time.

It will be appreciated by those skilled in the art having the benefit of this disclosure that an embodiment of the present invention provides a chip carrier tape adapted to carry multiple chip sizes and/or shapes. It should be understood that the drawings and detailed description herein are to be regarded in an illustrative rather than a restrictive manner, and are not intended to limit the invention to the particular forms and examples disclosed. On the contrary, the invention includes any further modifications, changes, rearrangements, substitutions, alternatives, design choices, and embodiments apparent to those of ordinary skill in the art, without departing from the spirit and scope of this invention, as defined by the following claims. Thus, it is intended that the following claims be interpreted to embrace all such further modifications, changes, rearrangements, substitutions, alternatives, design choices, and embodiments.

What is claimed is:

1. A chip carrier tape comprising:
a tape member; and
a plurality of pockets formed in and along the tape member, each of the pockets comprising a first portion and a second portion, the first portion having a shape and size adapted to fit a first chip size therein, the second portion having a shape and size adapted to fit a second chip size therein, wherein the first chip size differs from the second chip size, wherein the first portion includes a first pocket volume that is not part of the second portion, and wherein the second portion includes a second pocket volume that is not part of the first portion.

2. The chip carrier tape of claim 1, wherein each of the pockets has a depth that allows only one chip to be held therein at a time.

3. The chip carrier tape of claim 1, wherein each of the pockets has a depth that allows for two or more chips to be held therein at a time in a stacked configuration, and wherein the first portion is at a different pocket depth than the second portion.

4. The chip carrier tape of claim 3, wherein each of the pockets is adapted to contain one chip of each different chip size up to a total of two chips at a time.

5. The chip carrier tape of claim 1, wherein each of the pockets is adapted to contain one chip of each different chip size up to a total of two or more chips at a time.

6. The chip carrier tape of claim 1, wherein each of the pockets has a cross shape formed from the first portion intersecting the second portion.

7. The chip carrier tape of claim 1, wherein each of the pockets further comprises a third portion, the third portion having a shape and size adapted to fit a third chip size therein, and the third chip size being different from the first and second chip sizes.

8. The chip carrier tape of claim 7, wherein each of the pockets further comprises a fourth portion, the fourth portion having a shape and size adapted to fit a fourth chip size therein, and the fourth chip size being different from the first, second, and third chip sizes.

9. The chip carrier tape of claim 1, wherein at least one of the pockets comprises at least one integrated circuit chip therein.

10. A chip carrier tape comprising:
a tape member; and
a plurality of pockets formed in and along the tape member, each of the pockets having a cross shape formed from a first portion intersecting a second portion, the first portion having a shape and size adapted to fit a first chip size therein, the second portion having a shape and size adapted to fit a second chip size therein, wherein the first chip size differs from the second chip size.

11. The chip carrier tape of claim 10, wherein each of the pockets further comprises a third portion intersecting both the first and second portions, the third portion having a shape and size adapted to fit a third chip size therein, and the third chip size being different from the first and second chip sizes.

12. The chip carrier tape of claim 11, wherein each of the pockets further comprises a fourth portion intersecting both the first, second, and third portions, the fourth portion having a shape and size adapted to fit a fourth chip size therein, and the fourth chip size being different from the first, second, and third chip sizes.

13. The chip carrier tape of claim 10, wherein the first and second portions are located at a first pocket depth, each of the pockets further comprises a third portion located at a second pocket depth, and the first pocket depth differs from the second pocket depth.

14. The chip carrier tape of claim 10, wherein at least one of the pockets comprises at least one integrated circuit chip therein.

15. A chip carrier tape comprising:
a tape member; and
a plurality of pockets formed in and along the tape member, each of the pockets comprising a first portion and a second portion,
the first portion having a shape and size adapted to fit a first chip size therein, and the first portion being located at a first pocket depth,
the second portion having a shape and size adapted to fit a second chip size therein, and the second portion being located at a second pocket depth,
wherein the first chip size differs from the second chip size, and
wherein the first pocket depth differs from the second pocket depth.

16. The chip carrier tape of claim 15, wherein each of the pockets is adapted to contain one chip of each different chip size up to a total of two or more chips at a time.

17. The chip carrier tape of claim 15, wherein each of the pockets further comprises a third portion intersecting the first portion, the third portion having a shape and size adapted to fit a third chip size therein, and the third portion being located at the first pocket depth, wherein the third chip size differs from the first and second chip sizes.

18. The chip carrier tape of claim 17, wherein each of the pockets further comprises a fourth portion intersecting the second portion, the fourth portion having a shape and size adapted to fit a third chip size therein, and the fourth portion being located at the second pocket depth, wherein the fourth chip size differs from the first, second, and third chip sizes.

19. The chip carrier tape of claim 15, wherein at least one of the pockets comprises at least one integrated circuit chip therein.

20. A chip carrier tape comprising:
a tape member;
a plurality of pockets formed in and along the tape member, each of the pockets comprising a main portion and a first slotted portion, the first slotted portion intersecting the main portion, wherein the first slotted portion is adapted to receive a tab insert therein; and
wherein a first chip portion of the pocket is defined within the main portion when the tab insert is located within the first slotted portion, the first chip portion having a shape and size adapted to fit a first chip size therein,
wherein a second chip portion of the pocket is defined within the main portion and across the first slotted portion when the tab insert is absent from the first slotted portion, the second chip portion having a shape and size adapted to fit a second chip size therein, and
wherein the first chip size differs from the second chip size.

21. The chip carrier tape of claim 20, wherein each of the pockets further comprises a second slotted portion intersecting the main portion,
wherein a third chip portion of the pocket is defined within the main portion when the tab insert is located within the second slotted portion, the third chip portion having a shape and size adapted to fit a third chip size therein, and
wherein the third chip size differs from the first and second chip sizes.

22. The chip carrier tape of claim 20, wherein the main portion and the first slotted portion are located at a first pocket depth, each of the pockets further comprises a third portion located at a second pocket depth, the third portion has a shape and size adapted to fit a third chip size therein, the third chip size differs from the first and second chip sizes, and the first pocket depth differs from the second pocket depth.

23. The chip carrier tape of claim 20, wherein at least one of the pockets comprises at least one integrated circuit chip therein.

24. A method of selling integrated circuit chips after the chips are fabricated, comprising:
providing a chip carrier tape, the chip carrier tape comprising:
a tape member, and
a plurality of pockets formed in and along the tape member, each of the pockets comprising a first portion and a second portion, the first portion having a shape and size adapted to fit a first chip size therein, the second portion having a shape and size adapted to fit a second chip size therein, wherein the first chip size differs from the second chip size, wherein the first portion includes a first pocket volume that is not part of the second portion, wherein the second portion includes a second pocket volume that is not part of the first portion;
loading at least one integrated circuit chip into at least one of the pockets; and
delivering the chip carrier tape, which is at least partially loaded, to a chip buyer.

25. The method of claim 24, further comprising:
after the chip carrier tape is at least partially loaded, winding and loading the chip carrier tape onto a reel.
